(19) United States
(12) Patent Application Publication
(10) Pub. No.: US 2025/0385485 A1
(43) Pub. Date: Dec. 18, 2025

(54) EDGE EMITTING SEMICONDCUTOR LASER DIODE; METHOD FOR PRODUCING A SEMICONDCUTOR LASER DEVICE AND SEMICONDCUTOR LASER DEVICE

(71) Applicant: ams-OSRAM International GmbH, Regensburg (DE)

(72) Inventors: Mariel Grace JAMA, Regensburg (DE); Sven GERHARD, Alteglofsheim (DE)

(21) Appl. No.: 19/106,765

(22) PCT Filed: Jul. 27, 2023
(86) PCT No.: PCT/EP2023/070860

§ 371 Date: Feb. 26, 2025

(30) Foreign Application Priority Data
Aug. 30, 2022 (DE) 10 2022 121 857.0

(51) Int. Cl. H01S 5/042; H01S 5/0237; H01S 5/026

(52) U.S. Cl. CPC H01S 5/0421; H01S 5/0237; H01S 5/0268

(57) ABSTRACT

An edge emitting semiconductor laser diode includes a semiconductor layer sequence having a first semiconductor layer of a first conductivity type and a second semiconductor layer of a second conductivity type and an active region for generating electromagnetic laser radiation during operation, a ridge waveguide in a main surface of the semiconductor layer sequence, a first electrical contact layer on the main surface of the semiconductor layer sequence, and a second electrical contact layer on the ridge waveguide. The active region is between the first semiconductor layer and the second semiconductor layer. The first electrical contact layer electrically contacts the first semiconductor layer. The second electrical contact layer electrically contacts the second semiconductor layer. The first electrical contact layer is on the second electrical contact layer, such that electrical mounting areas of the edge emitting semiconductor laser diode are arranged in a common plane.

An edge emitting semiconductor laser diode, a method for producing a semiconductor laser device and a semiconductor laser device are provided.

An improved edge emitting semiconductor laser diode is to be provided. Particularly, an edge emitting semiconductor laser diode is to be provided that is easily integrable with a photonic integrated circuit. Further, a simplified method for producing a semiconductor laser device and an improved semiconductor laser device are to be provided.

These objects are achieved with an edge emitting semiconductor laser diode with the features of claim 1, a method for producing a semiconductor laser device with the steps of claim 14 and a semiconductor laser device with the features of claim 17.

Further embodiments and developments of the edge emitting semiconductor laser diode, the method for producing a semiconductor laser device and the semiconductor laser device are given in the dependent claims.

According to an embodiment, the edge emitting semiconductor laser diode comprises a semiconductor layer sequence having a first semiconductor layer of a first conductivity type and a second semiconductor layer of a second conductivity type. For example, the first conductivity type is an n-conductive type and the second conductivity type is a p-conductive type. In that case, the first semiconductor layer is an n-doped semiconductor layer and the second semiconductor layer is a p-doped semiconductor layer. It is also possible that the first conductivity type is p-conductive type and the second conductivity type is an n-conductive type. In that case the first semiconductor layer is p-doped and the second semiconductor layer is n-doped.

For example, the semiconductor layer sequence is based on a nitride semiconductor compound material and particularly configured to generate electromagnetic laser radiation from the ultraviolet to blue spectral range. Nitride compound semiconductor materials are compound semiconductor materials containing nitrogen, such as the materials from the system InₓAl_{y}Ga_{1-x-y}N with 0≤x≤1, 0≤y≤1 and x+y≤1.

According to a further embodiment of the edge emitting semiconductor laser diode, an active region is arranged between the first semiconductor layer and the second semiconductor layer, wherein the active region is configured for generating electromagnetic laser radiation during operation of the edge emitting semiconductor laser diode.

According to a further embodiment, the edge emitting semiconductor laser diode comprises a ridge waveguide in a main surface of the semiconductor layer sequence. The ridge waveguide is, in particular, a protrusion in the main surface of the semiconductor layer sequence and configured for guiding the electromagnetic laser radiation. For example, the ridge waveguide has a height not exceeding 800 nanometer. Particularly, a side face of the ridge waveguide being part of a facet of the edge emitting semiconductor laser diode comprises a light exit area of the semiconductor layer sequence, the light exit area emits electromagnetic laser radiation during operation.

The main surface of the semiconductor layer sequence has a normal corresponding to a growth direction of semiconductor layers of the semiconductor layer sequence. Further, the ridge waveguide particularly extends in a longitudinal direction being parallel to the main surface. In particular, the longitudinal direction corresponds to an propagation direction of the electromagnetic laser radiation.

According to a further embodiment, the edge emitting semiconductor laser diode comprises a first electrical contact layer arranged on the main surface of the semiconductor layer sequence, the first electrical contact layer electrically contacting the first semiconductor layer. Particularly, the first electrical contact layer comprises or consists of a metal. For example, the first electrical contact layer has a thickness between 200 nanometer and 3 micrometer, limits inclusive.

According to a further embodiment, the edge emitting semiconductor laser diode comprises a second electrical contact layer arranged on the ridge waveguide, the second electrical contact layer electrically contacting the second semiconductor layer. In order to provide electrical contact to the second semiconductor layer, the second electrical contact layer is, in particular, at least partially in direct contact with the second semiconductor layer. Particularly, the second electrical contact layer comprises or consists of a metal, such as Pd. For example, the second electrical contact layer has a thickness between 20 nanometer and 200 nanometer, limits inclusive.

According to a further embodiment of the edge emitting semiconductor laser diode, the second electrical contact layer has a thickness of between and including 2% to 20% of the thickness of the first electrical contact layer.

According to a further embodiment of the edge emitting semiconductor laser diode, the first electrical contact layer is arranged on the second electrical contact layer, such that electrical mounting areas of the edge emitting semiconductor laser diode are arranged in a common plane. It is clear for a person skilled in the art that “the electrical mounting areas are arranged in a common plane” is meant within limits of production tolerance. For example, uppermost places of the surfaces of the electrical mounting areas do not deviate from the common plane by at most 15%, at most 5% or at most 2%.

The edge emitting semiconductor laser diode is particularly based on the idea to arrange the first electrical contact layer electrically contacting the first semiconductor layer and having a comparatively high thickness also on the second electrical contact layer being comparatively thin in order to achieve electrical contact pads having electrical mounting areas at the same height. In such a way, a surface mountable edge emitting semiconductor laser diode can be achieved.

Particularly, the edge emitting semiconductor laser diode is a flip chip having electrical mounting areas on the same face such that the electrical mounting areas can be mounted to a further element, for example a photonic integrated circuit, by a joining layer. The joining material of the joining layer is, for example, a solder. The edge emitting semiconductor laser diode in flip chip design has the advantage that no wire bonding is required for external electrical connection.

According to a further embodiment, the edge emitting semiconductor laser diode comprises:
a semiconductor layer sequence having a first semiconductor layer of a first conductivity type and a second semiconductor layer of a second conductivity type and an active region configured for generating electromagnetic laser radiation during operation, the active region being arranged between the first semiconductor layer and the second semiconductor layer,
a ridge waveguide in a main surface of the semiconductor layer sequence,
a first electrical contact layer arranged on the main surface of the semiconductor layer sequence, the first electrical contact layer electrically contacting the first semiconductor layer,
a second electrical contact layer arranged on a main surface of the ridge waveguide, the second electrical contact layer electrically contacting the second semiconductor layer, wherein
the first electrical contact layer is arranged on the second electrical contact layer, such that electrical mounting areas of the edge emitting semiconductor laser diode are arranged in a common plane.

According to a further embodiment, the edge emitting semiconductor laser diode comprises an electrically insulating layer that electrically insulates a part of the first electrical contact layer electrically contacting the first semiconductor layer and a part of the first electrical contact layer arranged on the second electrical contact layer. Particularly, the first electrical contact layer is structured and comprises different parts being non-contiguous. In particular, the first electrical contact layer comprises or consist of at least two parts being arranged in the same plane but not connected to each other, one part electrically contacting the first semiconductor layer and one part being arranged on the second electrical contact layer. The electrically insulating layer is also at least partially arranged in the same plane as the first electrical contact layer and arranged in a region between the two parts of the first electrical contact layer in order to electrically insulate them.

Particularly, the electrically insulating layer is arranged in an opening of the first electrical contact layer and fills the opening preferably completely. For example, the insulating layer is in direct contact with the semiconductor layer sequence within the opening of the first electrical contact layer.

According to a further embodiment of the edge emitting semiconductor laser diode, the electrically insulating layer is a distributed Bragg reflector. Particularly, the electrically insulating layer being a distributed Bragg reflector, extends over the first main surface of the semiconductor layer sequence and over a side face of the semiconductor layer sequence, the side face including facets with the light exit surface of the edge emitting semiconductor laser diode. In that case, the distributed Bragg reflector forms preferably a resonator for the electromagnetic laser radiation on the facets of the edge emitting semiconductor laser diode. Particularly, the electrically insulating layer, being a distributed Bragg reflector, has a lower thickness on the side face of the semiconductor layer sequence than on the main surface of the semiconductor layer sequence, for example due to process reasons.

For example, the electrically insulating layer has a thickness of at least 0.5 micrometer, of at least 1 micrometer or of at least 3 micrometer over the main surface of the semiconductor layer sequence. On the side face of the semiconductor layer sequence the electrically insulating layer, being a distributed Bragg reflector, has for example a thickness of at least 200 nanometer, of at least 500 nanometer or of at least 900 nanometer. For example, the distributed Bragg reflector comprises or consists of alternating SiO₂ layers and SiN layers. For example, the layers of the distributed Bragg reflector are deposited by PCVD (short for “plasma chemical vapour deposition”).

According to a further embodiment of the edge emitting semiconductor laser diode, the electrically insulating layer has at least two openings and the first electrical contact layer and an electrical pad layer are arranged in direct contact within the openings. For example, the electrically insulating layer is arranged between the first electrical contact layer and the electrical pad layer within the electrical contact pad, except within the opening.

According to a further embodiment of the edge emitting semiconductor laser diode, the ridge waveguide is partially arranged in at least one opening of the electrically insulating layer. In particular, the electrically insulating layer exceeds the ridge waveguide in the vertical direction. In other words, the electrically insulating layer has a thickness greater than the height of the ridge waveguide. In such a way, the ridge waveguide is protected, in particular during joining with a further element. Particularly preferably, the first electrical contact layer is arranged over the ridge waveguide at least within the opening, further protecting the ridge waveguide and for heat dissipation during operation. Also, the electrical pad layer is preferably arranged within the opening, for example in direct contact with the first electrical contact layer.

If the ridge waveguide is partially arranged within in at least one opening of the electrically insulating layer, and the ridge waveguide is covered with the first electrical contact layer, the electrically insulting layer also exceeds the first electrical contact layer, preferably. In the case that there is also the electrical pad layer provided covering the first electrical contact layer, the electrically insulting layer also exceeds preferably the electrical pad layer.

Particularly, the ridge waveguide is covered by the second electrical contact layer, the first electrical contact layer and the electrical pad layer in at least one opening of the electrically insulating layer. Here, the second electrical contact layer is preferably arranged between the ridge waveguide and the first electrical contact layer. In particular, over the ridge waveguide the following layers are arranged in direct contact with each other in the given order:
second electrical contact layer,
first electrical contact layer,
electrical pad layer.

According to a further embodiment of the edge emitting semiconductor laser diode, the semiconductor layer sequence has a via penetrating the semiconductor layer sequence from the main surface. For example, the via penetrates the semiconductor layer sequence completely until a substrate onto which the semiconductor layer sequence is applied. This is in particular the case, if the substrate is electrically conductive. It is also possible that the via penetrates the semiconductor layer sequence only until the first semiconductor layer. Particularly, the first electrical contact layer is in direct physical contact with the first semiconductor layer and/or the substrate in the via. Particularly, the via runs parallel to the ridge waveguide.

According to a further embodiment of the edge emitting semiconductor laser diode, the via runs parallel to the ridge waveguide and divides the semiconductor layer sequence in a first region and in a second region in plan view on the main surface of the semiconductor layer sequence. This geometry leads to a good current distribution within the semiconductor layer sequence.

According to a further embodiment of the edge emitting semiconductor laser diode, the electrical pad layer is at least partially comprised by at least one first electrical contact pad and by at least one second electrical contact pad. The first electrical contact pad is arranged in the first region and the second electrical contact pad is arranged in the second region. Particularly, the first electrical contact pad is configured for externally electrically contacting the first semiconductor layer and the second electrical contact pad is configured for externally electrically contacting the second semiconductor layer.

Particularly preferably, a surface of the first electrical contact pad and a surface of the second electrical contact pad comprises or forms the electrical mounting areas of the edge emitting semiconductor laser diode.

According to a further embodiment of the edge emitting semiconductor laser diode, the first electrical contact pad and/or the second electrical contact pad have a circular geometry in plan view on the main surface of the semiconductor layer sequence. For example, the edge emitting semiconductor laser diode has three first electrical contact pads which are arranged in the first region of the semiconductor layer sequence and three second electrical contact pads that are arranged in a second region of the semiconductor layer sequence. Particularly, the three first electrical contact pads are arranged in a line parallel to the ridge waveguide and to an edge of the edge emitting semiconductor laser diode. Also, the three second electrical contact pads are particularly preferably arranged in a line parallel to the ridge waveguide and to an edge of the edge emitting semiconductor laser diode.

According to a further embodiment of the edge emitting semiconductor laser diode, the electrically insulating layer is arranged on or over the semiconductor layer sequence, at least in places. The electrically insulating layer has at least one cut-out in a border area. Particularly, the main surface of the semiconductor layer sequence is freely accessible in the cut-out. This has the advantage that the surface is very well defined relative to the ridge waveguide comprising the light exit area of the edge emitting semiconductor laser diode.

The edge emitting semiconductor laser diode is configured to be part of a semiconductor laser device. In the following, a method for producing a semiconductor laser device and a semiconductor laser device are described. Features and embodiments described in connection with the edge emitting semiconductor laser diode can also be embodied by the semiconductor laser device and the method for producing the semiconductor laser device and vice versa.

According to an embodiment of the method for producing a semiconductor laser device, an edge emitting semiconductor laser diode is provided, in particular as already described. In particular, the edge emitting semiconductor laser diode has at least two electrical mounting areas on the same face.

In other words, the edge emitting semiconductor laser diode is embodied as a flip chip. Preferably, electrical mounting areas of the edge emitting semiconductor laser diode are arranged in a common plane.

According to an embodiment of the method, a photonic integrated circuit with external mounting pads is provided. Particularly, the photonic integrated circuit has at least two external mounting pads being configured that the edge emitting semiconductor laser diode is mounted with the electrical mounting areas to the external mounting pads.

According to a further embodiment of the method, the electrical mounting areas of the edge emitting semiconductor laser diode are mechanically stable and electrically conductively connected with the external mounting pads.

According to a further embodiment of the method, an electrically insulating layer is arranged on or over the semiconductor layer sequence at least in places. The electrically insulating layer has at least one cut-out in a border area. Preferably, the main surface of the semiconductor layer sequence is freely accessible in the cut-outs. Further, the photonic integrated circuit has at least one z-alignment structure that is inserted in the cut-out during connection of the electrical mounting areas of the edge emitting semiconductor laser diode with the external mounting pads. The z-alignment structure of the photonic integrated circuit is particularly configured at least for alignment of the edge-emitting semiconductor laser diode in a growth direction of the semiconductor layer sequence.

According to a further embodiment of the method, connecting the electrical mounting areas of the edge emitting semiconductor laser diode to the external mounting pads comprises arranging a solid solder forming at least partially the external mounting pads, and arranging the electrical mounting areas of the edge emitting semiconductor laser diode on the solid solder with an offset. In particular, the solid solder is liquefied, particularly after arranging the electrical mounting areas of the edge emitting semiconductor laser diode on the solid solder. Liquefying is for example achieved by a reflow process. Particularly, the liquid solder wets the electrical mounting areas of the edge emitting semiconductor laser diode and The liquid solder moves the edge emitting semiconductor laser diode such that a light exit area of the edge emitting semiconductor laser diode self-aligns with an active optical element of the photonic integrated circuit. Particularly, a circular geometry of the electrical contact pads of the edge emitting semiconductor laser diode allows control of the movement of the edge emitting semiconductor laser diode in the self-aligned process.

In particular, during reflow of the liquid solder surface tension forces, such as capillary forces, of the liquid solder moves the edge emitting semiconductor laser diode. This leads to a self-alignment of the edge emitting semiconductor laser diode by constraining such movements with the help of the z-alignment structure.

Besides the z-alignment structure arranged on the photonic integrated circuit, the edge emitting semiconductor laser diode might be provided with at least one x-alignment structure and at least one y-alignment structure also constraining the movement of the edge emitting semiconductor laser diode in x and y direction, x and y spanning a plane parallel to the main surface of the semiconductor layer sequence. Further, the y-direction corresponds to the longitudinal direction. For example, the x-alignment structure, the y-alignment structure and/or the z-alignment structure are manufactured lithographically. With the help of the x-alignment structure and/or the y-alignment structure integrated in the edge emitting semiconductor laser diode, high placement accuracy can be achieved during manufacturing of the semiconductor laser device.

Y alignment structures, are for example, disclosed in the German application DE 102022106009.8, which is herein incorporated by reference.

The active optical element is, for example, an optical waveguide. During self-alignment of the edge emitting semiconductor laser diode the light exit area is, for example placed on a light entrance area of the optical waveguide. Preferably, the light exit area of the edge emitting semiconductor laser diode covers the light entrance area of the optical waveguide.

The self-aligned process is particularly based on the idea that the edge emitting semiconductor laser diode is placed offset to a final position on the photonic integrated circuit and moved by restoring forces of the liquid solder to its final position, guided by the alignment structures and aligned in a vertical direction by the z-alignment structure, in an x direction by the x-alignment structure and in a longitudinal direction by the y-alignment structure. Thus easy manufacturing of the semiconductor laser device is achieved, particularly wherein elements of the photonic integrated circuit such as the light entrance surface of an optical waveguide, are accurately aligned with the light exit surface of the edge emitting semiconductor laser diode.

According to an embodiment, the semiconductor laser device comprises an edge emitting semiconductor laser diode. The edge emitting semiconductor laser diode emits electromagnetic laser radiation from a light exit area during operation.

According to a further embodiment, the semiconductor laser device comprises a photonic integrated circuit with an active optical element. The active optical element is aligned with the light exit area of the edge emitting semiconductor laser diode. In particular, the light exit area covers a light entrance area of the active optical element.

According to a further embodiment of the semiconductor laser device, an electrically insulating layer is arranged on the semiconductor layer sequence at least in places. For example, the electrically insulating layer is a distributed Bragg reflector being also arranged on facets and particularly on the light exit area of the edge emitting semiconductor laser diode.

The electrically insulating layer has preferably at least one cut-out in a border area. The photonic integrated circuit has at least one z-alignment structure inserted in the cut-out.

Preferably, in each cut-out exactly one z-alignment structure is inserted.

For example, the z-alignment structure is a column extending from a main surface of the photonic integrated circuit into the cut-out.

The edge emitting semiconductor laser diode as well as the semiconductor laser device might find application in data encryption, data security, random number generation, visualization, artificial reality or virtual reality. For example, the edge emitting semiconductor laser diode as well as the semiconductor laser device is part of a display, a telecommunication device or a detection device.

Particularly, the surface mountable edge emitting semiconductor laser diode is configured to be mounted to a photonic integrated circuit with a self-aligned process by the help of alignment structures, particularly z-alignment structures.

Further advantageous embodiments and developments of the edge emitting semiconductor laser diode, the method for manufacturing a semiconductor laser device and the semiconductor laser device result from the exemplary embodiments described below in connection with the Figures.

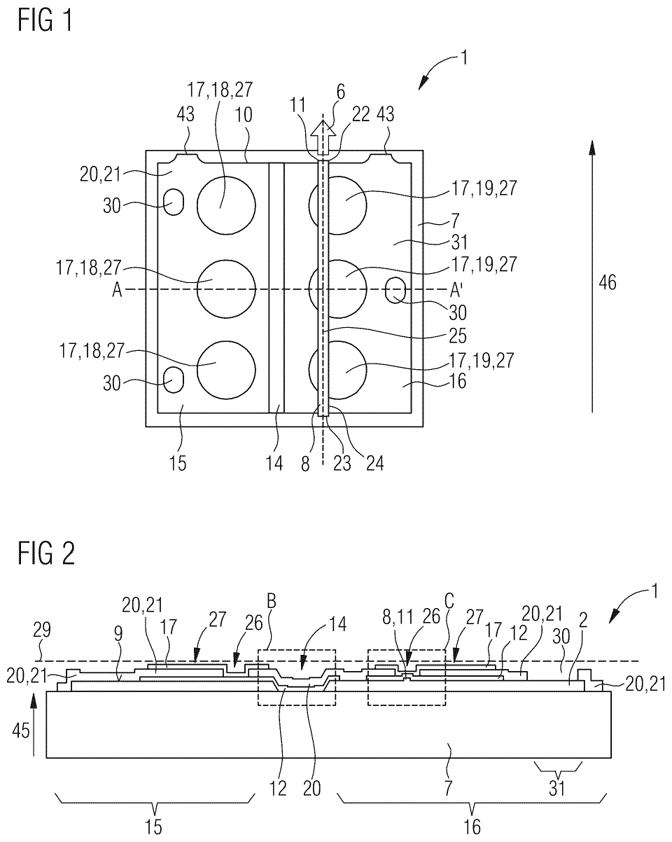

FIG. 1 schematically shows a plan view of an edge emitting semiconductor laser diode according to an exemplary embodiment.

FIG. 2 schematically shows a sectional view of the edge emitting semiconductor laser diode according to the exemplary embodiment of FIG. 1 along the line AA' of FIG. 1.

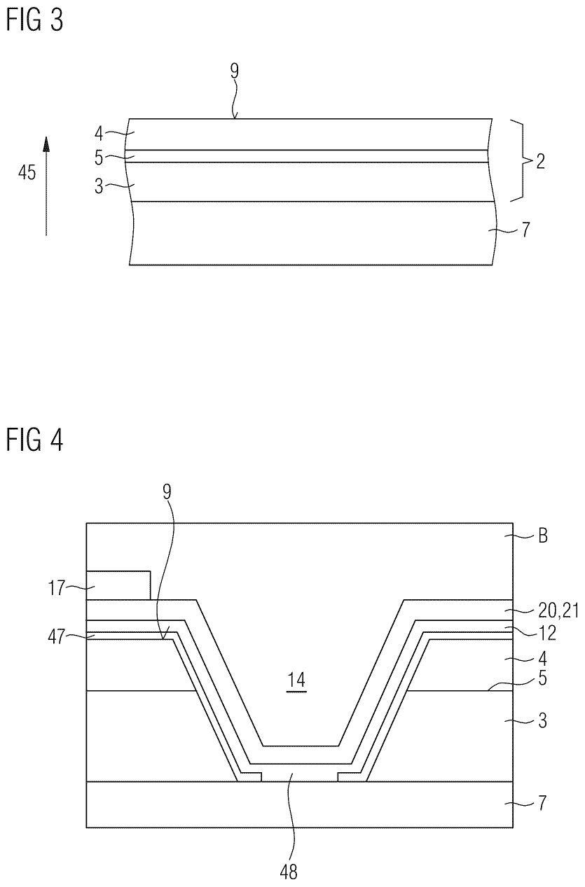

FIG. 3 schematically shows a semiconductor layer sequence on a substrate according to an exemplary embodiment.

FIG. 4 schematically shows the detail marked with B in FIG. 2.

FIG. 5 schematically shows the detail marked with C in FIG. 2.

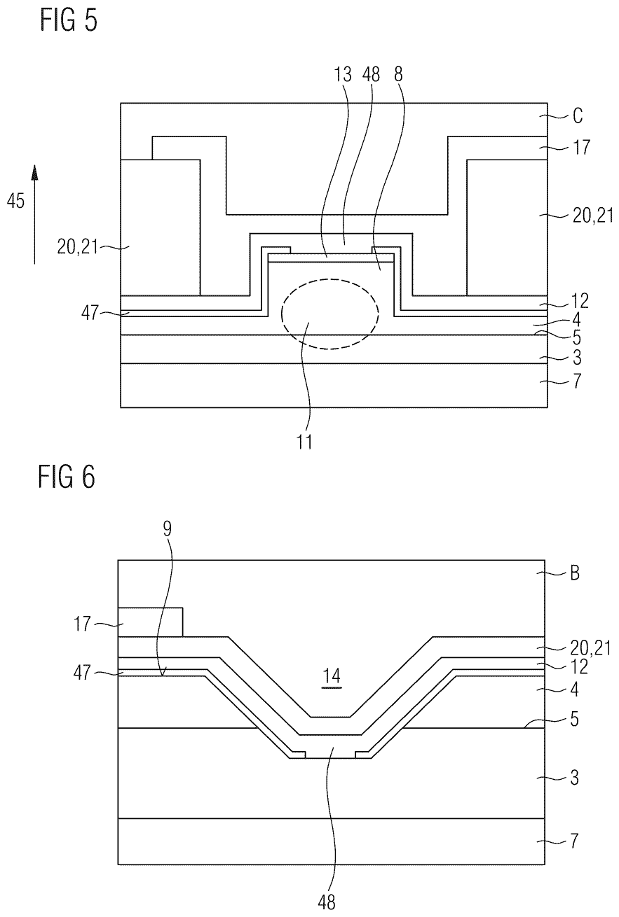

FIG. 6 shows an alternative exemplary embodiment of the detail marked with B in FIG. 2.

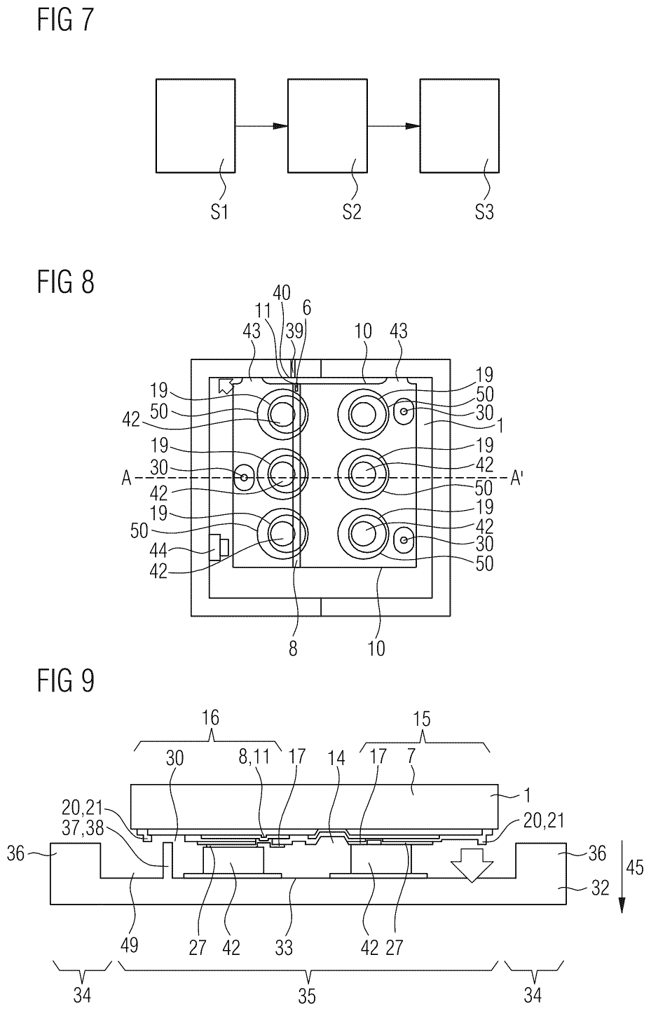

FIG. 7 shows a flow diagram of a method for manufacturing a semiconductor laser device according to an exemplary embodiment.

FIG. 8 schematically shows a stage of the method according to the exemplary embodiment of FIG. 7.

FIG. 9 schematically shows a sectional view of FIG. 8 along the line AA'.

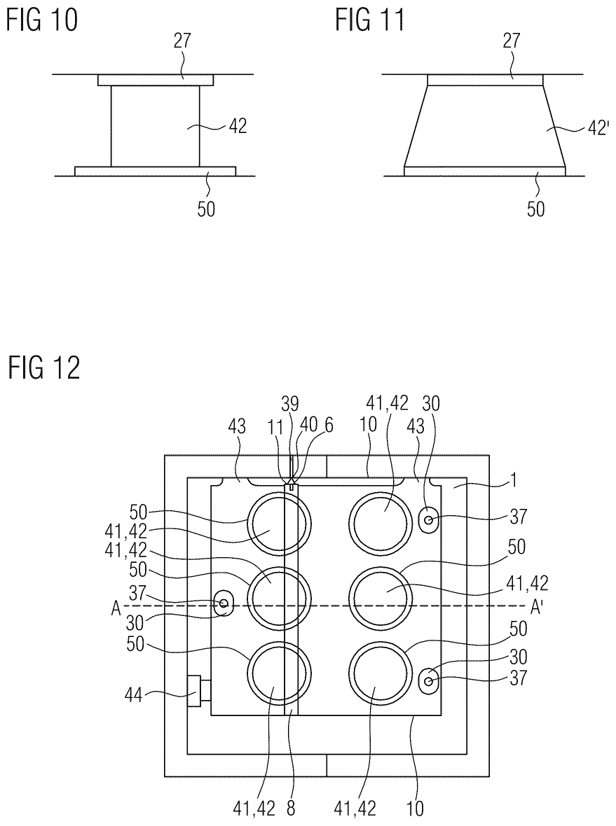

FIGS. 10 and 11 schematically show sectional views of stage of the method according to the exemplary embodiment of FIG. 7.

FIG. 12 schematically shows a plan view on a semiconductor laser device according to an exemplary embodiment.

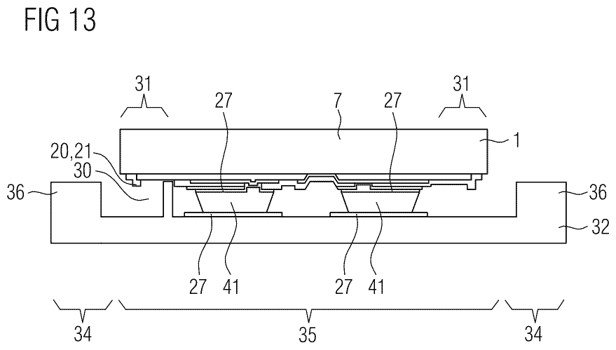

FIG. 13 schematically shows a sectional view along the line AA′ of FIG. 12.

Equal or similar elements as well as elements of equal function are designated with the same reference signs in the Figures. The Figures and the proportions of the elements shown in the Figures are not regarded as being shown to scale. Rather, single elements, in particular layers, can be shown exaggerated in magnitude for the sake of better presentation and/or better understanding.

The edge emitting semiconductor laser diode 1 according to the exemplary embodiment of FIGS. 1 to 5 comprises a semiconductor layer sequence 2 having a first semiconductor layer 3 of a first conductivity type and a second semiconductor layer 4 of a second conductivity type (FIGS. 2 and 3). Furthermore, the semiconductor layer sequence 2 comprises an active region 5 configured for generating electromagnetic laser radiation 6 during operation. The active region 5 is arranged between the first semiconductor layer 3 and the second semiconductor layer 4 (FIG. 3).

In the present exemplary embodiment, the first semiconductor layer 3 is an n-doped semiconductor layer being n-conductive, while the second semiconductor layer 4 is a p-doped semiconductor layer being p-conductive. The semiconductor layer sequence 2 is arranged on a substrate 7. For example, the substrate 7 is a growth substrate of the semiconductor layer sequence 2 and the semiconductor layer sequence 2 is epitaxially grown in a growth direction 45 on the substrate 7. At present, the substrate 7 comprises or consists of n-doped gallium nitride being electrically conductive.

Further, the edge emitting semiconductor layer sequence 2 comprises a ridge waveguide 8 being a protrusion in a main surface 9 of the semiconductor layer sequence 2 (FIGS. 1, 2 and 5). The ridge waveguide 8 guides the electromagnetic laser radiation 6 within the ridge waveguide 8 during operation of the edge emitting semiconductor laser diode 1 in a longitudinal direction 46.

The edge emitting semiconductor laser diode 1 comprises facets 10 at a side face, the facets 10 being at present etched and not produced by the help of scribing and breaking. A light exit area 11 emitting electromagnetic laser radiation 6 during operation is comprised by one facet 10 in the region of the ridge waveguide 8 (see FIG. 5).

The edge emitting semiconductor laser diode 1 comprises a first electrical contact layer 12 arranged on an insulation layer 47, which is arranged on the main surface 9 of the semiconductor layer sequence 2. The insulation layer is arranged between the semiconductor layer sequence 2 and the first electrical contact layer 12. The insulation layer 47 is configured for avoiding shorting the first semiconductor layer 3 and the second semiconductor layer 4 by the first electrical contact layer 12.

The edge emitting semiconductor laser diode 1 according to the exemplary embodiment of FIGS. 1 to 5 further comprises a via 14 in the main surface 9 of the semiconductor layer sequence 2. The via 14 enables electrical contact of the first semiconductor layer 3 by the first electrical contact layer 12. As shown in FIG. 4, the via 14 penetrates the semiconductor layer sequence 2 until the substrate 7. The first electrical contact layer 12 is in direct contact with the substrate 7 within the via 14. The via 14 runs parallel to the ridge waveguide 8 in the longitudinal direction 46 and divides the semiconductor layer sequence 2 in a first region 15 and in a second region 16 in plan view on the main surface 9 (FIG. 1).

Within the via 14, a feed-through 48 is arranged in the insulation layer 47 such that the first electrical contact layer 12 electrically contacts the first semiconductor layer 2. At present, the first electrical contact layer 12 is a n-contact layer. As can be seen, for example in FIG. 5, a second electrical contact layer 13 is arranged in direct contact on the ridge waveguide 8. The second electrical contact layer 13 electrically contacts the second semiconductor layer 4. At present, the second electrical contact layer 13 is a p-contact layer.

The edge emitting semiconductor laser diode 1 further comprises an electrical pad layer 17. The electrical pad layer 17 is at least partially comprised by three first electrical contact pads 18 and three second electrical contact pads 19 having a circular geometry, as can be seen in FIG. 1. The three first electrical contact pads 18 are arranged along a line being parallel to the via 14 and also to the ridge waveguide 8. The three second contacts pads 19 are also arranged on a line being arranged parallel to the ridge waveguide 8 and to the via 14.

Further, the edge emitting semiconductor laser diode 1 comprises an electrically insulating layer 20, which is at present a distributed Bragg reflector 21. The electrically insulating layer 20, embodied as a distributed Bragg reflector 21, covers the whole main surface 9 of the semiconductor layer sequence 2 and also the side face of the semiconductor layer sequence 2. Particularly, facets 10 of the edge emitting semiconductor laser diode 1 are covered by the distributed Bragg reflector 21. Particularly, a front side 22 of the ridge waveguide and a back side 23 of the ridge waveguide 8 are completely covered by the distributed

Bragg reflector 21, such that a resonator 24 for the electromagnetic laser radiation 6 generated within the active region 5 of the semiconductor layer sequence 2 is formed. The resonator 24 has an optical axis 25 extending along the ridge waveguide 8 parallel to the longitudinal direction 46.

Particularly, the distributed Bragg reflector 21 is highly reflective for the electromagnetic laser radiation 6.

Particularly, the first electrical contact layer 12 is in direct contact with the n-conductive substrate 7 in the via 14 (FIG. 4). Since the substrate 7 is electrically conductive, the first electrical contact layer 12, being in direct contact with the substrate 7, electrically contacts the first semiconductor layer 3 being in direct contact with the substrate 7. In direct contact, the electrically insulating layer 20 is arranged on the first electrical contact layer 12 in the via 14.

The first electrical contact layer 12 is structured such that a part of the first electrical contact layer 12 is arranged in the first region 15 and a second part of the first electrical contact layer 12 is arranged in the second region 16, a gap being arranged between the parts of the first electrical contact layer 12. The electrically insulating layer 20 fills the gap and electrically insulates the parts of the first electrical contact layer 12 from each other (FIG. 2).

Further, the electrically insulating layer 20 has openings 26. Three openings 26 of the electrically insulating layer 20 are arranged within the first region 15, while three openings 20 of the electrically insulating layer 20 are arranged in the second region 16. Within the openings 26 the electrical pad layer 17 and the first electrical contact layer 12 are arranged in direct contact.

In the openings 26 arranged in the second region 16 of the semiconductor layer sequence 2, the ridge waveguide 8 is partially arranged (FIGS. 2 and 5). The electrically insulating layer 20 has a height in the vertical direction 45 exceeding the ridge waveguide 8 in order to protect it. On the ridge waveguide 8, the second electrical contact layer 13 is arranged in direct contact with the semiconductor layer sequence 2.

On the semiconductor layer sequence 2 the insulation layer 47 is arranged in order to avoid shorting the first semiconductor layer 3 and the second semiconductor layer 4 by the first electrical contact layer 12. In the insulation layer 47 a further feedthrough 48 is arranged in order to allow electrical contact between the second electrical contact layer 13 and the first electrical contact layer 13 (FIG. 5).

Further, the first electrical contact layer 12 completely covers the ridge waveguide 8 within the opening 26. Also, the electrical pad layer 17 completely covers the ridge waveguide 8. Further, the arrangement of the first electrical contact layer 12, the electrically insulating layer 20 and the electrical pad layer 17 is in the regions of the electrical contact pads 17, 18 symmetrical to the via 14 (FIG. 2).

Surfaces of the electrical pad layer 17 form electrical mounting areas 27 of the edge emitting semiconductor laser diode 1 configured to be connected mechanically and/or electrically conductively to external mounting pads 28. The arrangement of the first electrical contact layer 12, the electrically insulating layer 20 and the electrical pad layer 17 in the first region 15 and in the second region 16 of the semiconductor layer sequence 2, particularly symmetrically, leads to electrical mounting areas 27 arranged in a common plane 29.

Further, the electrically insulating layer 20 comprises at present three cut-outs 30 in a border area 31 having a round, for example oval or circular geometry, in plan view (FIG. 1). The cut-outs 30 in the electrically insulating layer 20 expose the main surface 9 of the semiconductor layer sequence 2 (FIG. 2).

The edge emitting semiconductor laser diode 1 according to the exemplary embodiment of FIG. 6 is for example embodied as the edge emitting semiconductor laser diode 1 of the exemplary embodiment of FIGS. 1 to 5, except the geometry within the via 14. In contrast to the edge emitting semiconductor laser diode 1 of FIGS. 1 to 5, the via 14 does not completely penetrate the semiconductor layer sequence 2 until the substrate 7 but only through the second semiconductor layer 4 until the first semiconductor layer 3. The first electrical contact layer 12 electrically contacts the first semiconductor layer 3 within the via 14. The exemplary embodiment of the via 14 of FIG. 6 for electrical connection of the first semiconductor layer 3 is particularly reasonable, if a substrate 7 is used which is not electrically conductive, such as a sapphire substrate or if the first semiconductor layer 3 has a higher lateral electrical conductivity than the substrate in order to allow good current spreading in the semiconductor layer sequence 2.

In the method according to the exemplary embodiment of FIGS. 7 to 11, an edge emitting semiconductor laser diode 1 is provided in first step S1. The edge emitting semiconductor laser diode 1 is, for example, embodied as already described in connection with FIGS. 1 to 5.

In a next step S2, a photonic integrated circuit 32 is provided. For example, the photonic integrated circuit 32 comprises or consists of silicon. The photonic integrated circuit 32 has a base area 33 larger than the edge emitting semiconductor laser diode 1 and an extension plane parallel to the main surface 9 of the semiconductor layer sequence 2 (FIGS. 8 and 9). In an edge area 34 surrounding a central area 35 of the photonic integrated circuit 32, a frame-shaped elevation is comprised by the photonic integrated circuit 32. The photonic integrated circuit 32 comprises a z-alignment structure 37 being a column 38 extending from a main surface 49 of the photonic integrated circuit 32 against the vertical direction 45.

Further, the photonic integrated circuit 32 comprises an active optical element 39, at present an optical waveguide having a light entrance area 40.

On the main surface 49 of the photonic integrated circuit 32 a structured seed layer 50 for the deposition of a solid solder 42 is applied. On the seed layer 50 a solid solder 42 is deposited, for example galvanically, the solid solder 42 forming at least partially external mounting pads 28 of the photonic integrated circuit 32.

In particular, the solid solder 42 and the electrical mounting areas 27 of the edge emitting semiconductor laser diode 1 are circular at present. A diameter of the electrical mounting areas 27 of the edge emitting semiconductor laser diode 1 is larger than a diameter of the solid solder 42 (see FIGS. 10).

In a further step S3, the edge emitting semiconductor laser diode 1 is mechanically stable and electrically conductively connected with the photonic integrated circuit 32 by soldering.

For connecting the edge emitting semiconductor laser diode 1 to the photonic integrated circuit 32 by a solder joint 41, the edge emitting semiconductor laser diode 1 is arranged offset to the photonic integrated circuit 32 on the solid solder 42 forming external mounting pads 28 (FIG. 8). The edge emitting semiconductor laser diode 1 comprises an y-alignment structure 43 and an x-alignment structure 44 for lateral alignment of the edge emitting semiconductor laser diode 1 in a plane parallel to the main surface 9 of the semiconductor layer sequence 2.

Then the solid solder 42 is liquefied to a liquid solder 42′. The liquid solder 42′ wets the electrical mounting areas 27 of the edge emitting semiconductor laser diode 1 and a volume of the liquid solder 42′ redistributes by spreading to cover the whole electrical mounting areas 27. The redistribution of the volume of the liquid solder 42′ leads to a collapse in the height of the liquid solder 42′, thereby lowering the edge emitting semiconductor laser diode 1 (FIG. 11). The light exit area 11 of the edge emitting semiconductor laser diode 1 is aligned with the light entrance area 40 of the optical integrated circuit 32 by the lowering. After wetting of the electrical mounting areas 27 the liquid solder 42 has the same diameter as the electrical mounting areas 27. During wetting, the liquid solder 42′ moves the edge emitting semiconductor laser diode 1 guided by the y-alignment structure 43 and the x-alignment structure 44 in the correct position by a self-alignment process. The light exit area 11 of the edge emitting semiconductor laser diode 1 is aligned with the light entrance area 40 of the optical integrated circuit 32. Particularly, the light exit area 11 of the edge emitting semiconductor laser diode 1 and the light entrance area 40 of the optical waveguide being the active optical element 39 of the photonic integrated circuit 32 match with a high accuracy.

After the liquid solder 42 is applied to the external mounting pads 28, it wets the surface of the external mounting pads 28 such that the thickness of the liquid solder 42 is decreased. This leads to a lowering of the edge emitting semiconductor laser diode 1 to the photonic integrated circuit 32 and particularly to the z-alignment structure 37 being arranged within the cut-out 30 of the electrically insulating layer 20 of the edge emitting semiconductor laser diode 1 in a self-aligning process.

After self-alignment of the edge emitting semiconductor laser diode 1 and the integrated optical circuit 32, the liquid solder 31 solidifies to a solid solder joint 41 connecting the electrical mounting areas 27 and external mounting pads 28 mechanically stable and electrically conductive with each other.

The semiconductor laser device according to the exemplary embodiment of FIGS. 12 and 13 can be produced by the method already described in connection with FIGS. 7 to 11.

A semiconductor laser device according to the exemplary embodiment of FIGS. 12 and 13 comprises an edge emitting semiconductor laser diode 1 as already described in connection with FIGS. 1 to 5.

Further, the semiconductor laser device comprises a photonic integrated circuit 32 being connected to electrical mounting areas 27 of the edge emitting semiconductor laser diode 1 with the help of a solid solder joint 41. Further, the edge emitting semiconductor laser diode 1 comprises an electrically insulating layer 20 having three z-alignment structures 37 arranged in a border area 31. The z-alignment structures 37 are inserted in the cut-outs 30 of the electrically insulating layer 29 arranged in the border area 31.

Further, a light exit area 11 of the edge emitting semiconductor laser diode 1 covers a light entrance area 40 of an optical waveguide being part of the photonic integrated circuit 32. Electromagnetic laser radiation 6 emitted from the light exit area 11 of the edge emitting semiconductor laser diode 1 couples in the optical waveguide via the light entrance area 40.

The present application claims priority of the German application DE 102022121857.0, the disclosure content of which is incorporated herein by reference.

The invention is not limited to the description of the embodiments. Rather, the invention comprises each new feature as well as each combination of features, particularly each combination of features of the claims, even if the feature or the combination of features itself is not explicitly given in the claims or embodiments.

### REFERENCES

1 edge emitting semiconductor laser diode
2 semiconductor layer sequence
3 first semiconductor layer
4 second semiconductor layer
5 active region
6 electromagnetic laser radiation
7 substrate
8 ridge waveguide
9 main surface of the semiconductor layer sequence
10 facet
11 light exit area
12 first electrical contact layer
13 second electrical contact layer
14 via
15 first region
16 second region
17 electrical pad layer
18 first electrical contact pad
19 second electrical contact pad
20 electrically insulating layer
21 distributed Bragg reflector
22 front side of the ridge waveguide
23 back side of the ridge waveguide
24 resonator
25 optical axis
26 opening
27 mounting area
28 external mounting pad
29 common plane
30 cut-out
31 border area
32 photonic integrated circuit
33 base area
34 edge area
35 central area
36 elevation
37 z-alignment structure
38 column
39 active optical element
40 light entrance area
41 solder joint
42 solid solder
42′ liquid solder
43 y-alignment structure
44 x-alignment structure
45 growth direction
46 longitudinal direction
47 insulation layer
48 feed-through
49 main surface of the photonic integrated circuit
S1, S2, S3 method step

1. An edge emitting semiconductor laser diode comprising:
semiconductor layer sequence having a first semiconductor layer of a first conductivity type and a second semiconductor layer of a second conductivity type and an active region configured for generating electromagnetic laser radiation during operation, the active region being arranged between the first semiconductor layer and the second semiconductor layer,
a ridge waveguide in a main surface of the semiconductor layer sequence,
a first electrical contact layer arranged on the main surface of the semiconductor layer sequence, the first electrical contact layer electrically contacting the first semiconductor layer,
a second electrical contact layer arranged on the ridge waveguide, the second electrical contact layer electrically contacting the second semiconductor layer,
wherein
the first electrical contact layer is arranged on the second electrical contact layer, such that electrical mounting areas of the edge emitting semiconductor laser diode are arranged in a common plane,
an electrically insulating layer electrically insulates a part of the first electrical contact layer electrically contacting the first semiconductor layer and a part of the first electrical contact layer arranged on the second electrical contact layer,
the electrically insulating layer has at least two openings, and
the first electrical contact layer and an electrical pad layer are arranged in direct contact within the openings.

2. (canceled)

3. The edge emitting semiconductor laser diode according to claim 1, wherein the electrically insulating layer is a distributed Bragg reflector.

4. (canceled)

5. The edge emitting semiconductor laser diode according to claim 1, wherein
the ridge waveguide is partially arranged in at least one opening of the electrically insulating layer, and
the electrically insulating layer exceeds the ridge waveguide in a vertical direction.

6. The edge emitting semiconductor laser diode according to claim 1, wherein
the ridge waveguide is covered by the first electrical contact layer, the second electrical contact layer and the electrical pad layer in at least one opening of the electrically insulating layer.

7. The edge emitting semiconductor laser diode according to claim 1, wherein
the semiconductor layer sequence has a via penetrating the semiconductor layer sequence from the main surface, and
the first electrical contact layer is in direct physical contact with the first semiconductor layer and/or a substrate in the via.

8. The edge emitting semiconductor laser diode according to claim 7, wherein
the via runs parallel to the ridge waveguide, and
the via divides the semiconductor layer sequence in a first region and a second region in plan view on the main surface of the semiconductor layer sequence.

9. The edge emitting semiconductor laser diode according to claim 8, wherein
the electrical pad layer is at least partially comprised by at least one first electrical contact pad and by at least one second electrical contact pad,
the first electrical contact pad being arranged in the first region and the second electrical contact pad being arranged in the second region.

10. The edge emitting semiconductor laser diode according to the previous claim, wherein claim 9, wherein
the first electrical contact pad is configured for externally electrically contacting the first semiconductor layer, and
the second electrical contact pad is configured for externally electrically contacting the second semiconductor layer.

11. The edge emitting semiconductor laser diode according to claim 9, wherein the first electrical contact pad and/or the electrical second contact pad have a circular geometry in plan view on the main surface of the semiconductor layer sequence.

12. The edge emitting semiconductor laser diode according to claim 9, wherein three first electrical contact pads are arranged in the first region of the semiconductor layer sequence and three second electrical contact pads are arranged in the second region of the semiconductor layer sequence.

13. The edge emitting semiconductor laser diode according to claim 1, wherein
an electrically insulating layer is arranged on the semiconductor layer sequence at least in places,
the electrically insulating layer has at least one cut-out in a border area, and
the main surface of the semiconductor layer sequence is freely accessible in the cut-out.

14. A method for producing a semiconductor laser device comprising the following steps:
providing an edge emitting semiconductor laser diode according to claim 1,
providing a photonic integrated circuit with at least two external mounting pads,
connecting the edge emitting semiconductor laser diode with the photonic integrated circuit, wherein
the electrical mounting areas of the edge emitting semiconductor laser diode are mechanically stable and electrically conductively connected with the external mounting pads.

15. The method according to claim 14, wherein
an electrically insulating layer is arranged on or over the semiconductor layer sequence at least in places,
the electrically insulating layer has at least one cut-out in a border area, and,
the photonic integrated circuit has at least one z-alignment structure that is inserted in the cut-out during connecting the electrical mounting areas of the edge emitting semiconductor laser diode with the external mounting pads.

16. The method according to claim 14, wherein connecting the electrical mounting areas of the edge emitting semiconductor laser diode to the external mounting pads comprises:
arranging a solid solder forming at least partially the external mounting pads on the photonic integrated circuit, and
arranging the electrical mounting areas of the edge emitting semiconductor laser diode on the solid solder with an offset,
liquefying the solid solder to a liquid solder,
wherein
the liquid solder moves the edge emitting semiconductor laser diode such that a light exit area of the edge emitting semiconductor laser diode self-aligns with an active optical element of the photonic integrated circuit.

17. A semiconductor laser device comprising:
an edge emitting semiconductor laser diode according to claim 1, the edge emitting semiconductor laser diode emitting electromagnetic laser radiation from a light exit area during operation,
a photonic integrated circuit with an active optical element, the active optical element being aligned with the light exit area, wherein
an electrically insulating layer is arranged on the semiconductor layer sequence at least in places,
the electrically insulating layer has at least one cut-out in a border area,
the photonic integrated circuit has at least one z-alignment structure inserted in the cut-out.

18. The semiconductor laser device according to claim 17, wherein the z-alignment structure is a column extending from a main surface of the photonic integrated circuit in the cut-out.
